(19) United States
(12) Patent Application Publication
(10) Pub. No.: US 2012/0105665 A1
(43) Pub. Date: May 3, 2012

(54) DIGITAL IMAGE PICKUP APPARATUS, RADIATION IMAGING APPARATUS, AND RADIATION IMAGING SYSTEM

(75) Inventors: Kazumasa Matsumoto, Yokohama-shi (JP); Yuichi Naito, Yokohama-shi (JP); Hidehiko Saito, Saitama-shi (JP); Takashi Yamazaki, Kawasaki-shi (JP); Hiroaki Niwa, Kawasaki-shi (JP)

(73) Assignee: CANON KABUSHIKI KAISHA, Tokyo (JP)

(21) Appl. No.: 13/279,458

(22) Filed: Oct. 24, 2011

(30) Foreign Application Priority Data
Oct. 29, 2010 (JP) 2010-243800

(51) Int. Cl. H04N 5/335

(52) U.S. Cl. 348/222.1; 348/E05.091

(57) ABSTRACT

An image pickup apparatus includes an image sensor configured to include a plurality of pixels in its image pickup area; a plurality of analog-to-digital converters configured to share a plurality of analog signals read out from the plurality of pixels to perform analog-to-digital conversion to the analog signals allocated thereto; and a control unit configured to read out the analog signals from the pixels within a partial area in the image pickup area for the analog-to-digital conversion. The number of pixels allocated to the analog-to-digital converters performing the analog-to-digital conversion to areas near a center position of the partial area is smaller than that allocated to the analog-to-digital converters performing the analog-to-digital conversion to areas far from the center position of the partial area.

### BACKGROUND OF THE INVENTION

1. Field of the Invention

The present disclosure relates to an image pickup apparatus, a radiation imaging apparatus, and a radiation imaging system using an image sensor that converts radiation or light into a digital signal.

2. Description of the Related Art

Image sensors converting radiation or light into digital signals are in widespread use. In the field of radiography in recent years, digital X-ray sensors in which image sensors are combined with fluorescent members converting X-rays into light to electronically capture images of objects are commonly used.

Recent developments in semiconductor fabrication techniques have enabled the fabrication of image sensors with significantly large number of pixels. As result, in newer image sensors, the processing load is increased and the time from the start of sensing of light to the completion of transfer of images to external apparatuses, that is, the throughput, is reduced as the image quality is improved due to the increase in the number of pixels in the image sensors capturing the images. As countermeasures against the above problem, a technology to reduce the time required for analog-to-digital (A/D) conversion by concurrently performing the A/D conversion of analog signals generated in photoelectric conversion elements with multiple A/D converters is disclosed (U.S. Pat. No. 7,593,508). In addition, a technology to reduce the transfer time, by setting a limited readout range in which signals are read out from a partial area of an image sensor, is disclosed (Japanese Patent Laid-Open No. 5-208005).

However, there is a problem in that the effect of improvement of the throughput is suppressed by the A/D conversion time even with the limited readout range.

FIG. 14 is a diagram describing an image sensor 1400 that uses multiple A/D converters and that is capable of limiting the readout range to a central portion of the image sensor. Referring to FIG. 14, an image pickup area 1401 is a rectangular area indicating a readout range before limitation. A partial area 1402 is a rectangular area indicating a limited readout range in the image pickup area 1401. Allocated areas 1403a, 1403b, 1403c, and 1403d are allocated to the respective A/D converters. Each A/D converter performs A/D conversion to analog signals read out from pixels arranged in the corresponding allocated area.

When the readout range is limited to the partial area 1402, the A/D conversion of the partial area 1402 is performed by the two A/D converters to which the allocated areas 1403b and 1403c are allocated. Accordingly, the transfer time is reduced by the amount of decrease in the number of signals to be subjected to the A/D conversion. However, the A/D conversion time itself is not reduced as much as desired, as compared with the transfer time, because of the proportional decrease in the number of the A/D converters. It is difficult to distribute the processing load between many A/D converters when the readout range is limited.

In addition to the above technique of reducing transfer time, recent improvements in communication technologies have enabled even further improvements in the transfer speed of data between circuits. Accordingly, there is a problem in that the A/D conversion does not catch up with the transfer speed even with the limited readout range to suppress the effect of the improvement of the throughput. Although A/D converters having higher throughputs may be used or the number of A/D converters may be increased, the cost is undesirably increased in this case.

### SUMMARY OF THE INVENTION

According to an embodiment of the present invention, an image pickup apparatus includes an image sensor including a plurality of pixels that form an image pickup area; a plurality of analog-to-digital (A/D) converters configured to share a plurality of analog signals read out from the plurality of pixels to perform analog-to-digital conversion to the analog signals allocated thereto; and a control unit configured to read out the analog signals from pixels within a partial area of the image pickup area for the analog-to-digital conversion. A number of pixels allocated to the analog-to-digital converters performing the analog-to-digital conversion to areas near a center position of the partial area is smaller than a number of pixels allocated to the analog-to-digital converters performing the analog-to-digital conversion to areas far from the center position of the partial area.

Further features of the present invention will become apparent from the following description of exemplary embodiments with reference to the attached drawings.

### BRIEF DESCRIPTION OF THE DRAWINGS

FIG. 1 illustrates an example of the configuration of a radiation imaging system according to a first embodiment of the present invention.

FIG. 2 illustrates an image sensor and allocated areas of analog-to-digital (A/D) converters according to the first embodiment.

FIG. 3 illustrates an example of the configuration of a rectangular semiconductor substrate according to the first embodiment.

FIGS. 4A to 4C include time charts illustrating examples of control in which analog signals are read out from the image sensor according to the first embodiment.

FIG. 4A is a time chart indicating an example of readout control in an 11-inch mode; FIG. 4B is a time chart indicating an example of readout control in a 6-inch mode; and FIG. 4C is a time chart indicating another example of the readout control in the 6-inch mode.

FIGS. 5A to 5C include diagrams illustrating an example of cutting out sections of an image (cutout of an image) captured by the image sensor according to the first embodiment. FIG. 5A is a diagram illustrating an example of an entire image area readout in the 11-inch mode; FIG. 5B is a diagram illustrating an example of an image area readout in the 6-inch mode; and FIG. 5C is a diagram illustrating an example of an image area to be transferred to an information processing apparatus.

FIG. 6 illustrates an image sensor according to a second embodiment of the present invention.

FIG. 7 illustrates a circuit diagram showing an example of the configuration of pixels in an image sensor according to a fourth embodiment of the present invention.

FIG. 8 illustrates an example of the configuration of an image pickup apparatus according to a fifth embodiment of the present invention.

FIG. 9 illustrates an example of the configuration of a radiation imaging system according to a sixth embodiment of the present invention.

FIG. 10 illustrates an example of the configuration of a rectangular semiconductor substrate according to the sixth embodiment.

FIGS. 11A and 11B include time charts illustrating examples of control in which analog signals are read out from an image sensor according to the sixth embodiment. FIG. 11A is a time chart indicating an example of readout control in the 11-inch mode and FIG. 11B is a time chart indicating an example of readout control in the 6-inch mode.

FIG. 12 illustrates an example of the configuration of a radiation imaging system including an image sensor as a comparative example.

FIGS. 13A to 13C include time charts illustrating examples of readout control in the image sensor as the comparative example. FIG. 13A is a time chart indicating an example of the readout control in the 11-inch mode as the comparative example; FIG. 13B is a time chart indicating an example of the readout control in the 6-inch mode as the comparative example; and FIG. 13C is a time chart indicating another example of the readout control in the 6-inch mode as the comparative example.

FIG. 14 is a diagram illustrating the relationship between a readout range and analog-to-digital conversion areas in an image sensor in related art.

### DESCRIPTION OF THE EMBODIMENTS

Embodiments of the present invention will herein be described with reference to the attached drawings. In the following specification and claims, the term “radiation” is used to describe various kinds of radiation including particle beams such as alpha rays, beta rays, gamma rays, etc., radiated via radioactive decay, and other beams with high energy similar to that of particle beams. For example, X-ray radiation, cosmic radiation, etc., also fall under the scope of radiation as used in the present application. As applied to medical imaging and non-destructive inspection and testing, the term radiation may preferably refer to X-ray radiation, but it is not limited thereto.

### First Embodiment

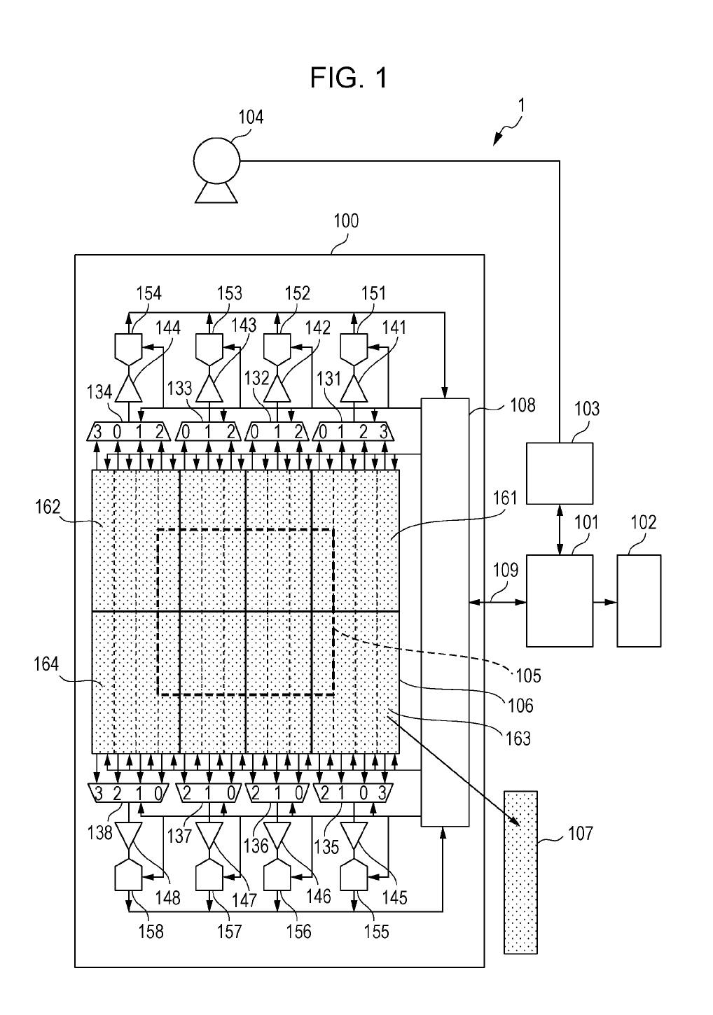

A first embodiment will now be described with reference to FIG. 1 to FIGS. 5A to 5C. FIG. 1 illustrates an example of the configuration of a radiation imaging system 1 according to the first embodiment.

Referring to FIG. 1, an image pickup apparatus 100 converts radiation transmitted through an object into light with a scintillator (not shown). The image pickup apparatus 100 detects the light to capture a frame image corresponding to the amount of detected light. The frame image is transferred to an information processing apparatus 101. The information processing apparatus 101 performs image processing to the frame image data.

In addition, the information processing apparatus 101 functions as a display controller for an image display apparatus 102 and causes the image display apparatus 102 to display the image subjected to the image processing. The image capturing, the transfer, and the display are sequentially performed and the information processing apparatus 101 is capable of causing the image display apparatus 102 to display moving images in real time during the capturing of images of the object. The information processing apparatus 101 is also capable of causing the image display apparatus 102 to capture still images and display the still image. The information processing apparatus 101 synchronously controls a radiation generating apparatus 103 and the image pickup apparatus 100.

The radiation generating apparatus 103 controls generation of radiation by a radiation source 104. The radiation source 104 is, for example, an X-ray tube and radiates the radiation in accordance with a tube current and a tube voltage controlled by the radiation generating apparatus 103. The radiation generating apparatus 103 is capable of setting an irradiation area of the radiation generated by the radiation source 104.

In the embodiments of the present invention, the detection of light by an image sensor to generate an image is called image capturing. A series of operations including the image capturing, the transfer of the captured image from the image sensor, and the supply of the image to a recording medium or a display device is called imaging.

An example of the configuration of the image pickup apparatus 100 will now be described. The image pickup apparatus 100 includes multiple A/D converters and is capable of limiting a readout range of an image sensor 106.

The image sensor 106 is an image pickup device in which multiple pixels are arranged in an image pickup area. The multiple pixels are mounted on each rectangular semiconductor substrate 107. Multiple rectangular semiconductor substrates 107 are tiled on a planar base (not shown) in a matrix pattern of 14 columns×two rows, thereby composing the image sensor 106. Each rectangular semiconductor substrate 107 cut out in a strip shape has a width of about 20 mm and a length of about 140 mm. Accordingly, the image sensor 106 resulting from the tiling of the rectangular semiconductor substrates 107 in the matrix pattern of 14 columns×two rows is about 11 inches square, that is, has a square shape measuring about 280 mm per side.

One rectangular semiconductor substrate 107 may operate as an area sensor. Each rectangular semiconductor substrates 107 is manufactured by cutting out two-dimensional photoelectric conversion elements in a strip shape from a silicon semiconductor wafer. Pixel circuits to acquire analog signals generated by the photoelectric conversion elements are provided on the rectangular semiconductor substrate 107. The photoelectric conversion element and the pixel circuit compose each pixel.

The multiple pixels are two-dimensionally aligned on each rectangular semiconductor substrate 107 at regular intervals. The rectangular semiconductor substrates 107 are tiled so that the pitch of the adjacent pixels with the boundary between the rectangular semiconductor substrates sandwiched therebetween is equal to the pitch of the adjacent pixels in each rectangular semiconductor substrate 107.

Analog multiplexers 131 to 138 each select the outputs from the pixels for every substrate in accordance with a control signal from an image pickup control unit 108 and supply the selected outputs to amplifiers 141 to 148 connected to the analog multiplexers 131 to 138, respectively.

External terminals (electrode pads) (not shown) of the rectangular semiconductor substrates 107 aligned in the matrix pattern are aligned in rows along the upper side and the bottom side of the image sensor 106. The electrode pads of the rectangular semiconductor substrates 107 are connected to the analog multiplexers 131 to 138 via a printed circuit board (not shown) using flying-lead connectors. The selection of the substrates by the analog multiplexers 131 to 138 realizes the reading out of signals from the pixels in the image sensor 106. The signals of the pixels are read out from the respective analog multiplexers in parallel in the image sensor 106.

A/D converters 151 to 158 are connected to column signal lines in the image sensor 106 via the analog multiplexers 131 to 138, respectively. The A/D converters 151 to 158 convert analog signals from the amplifiers 141 to 148, respectively, into digital signals (perform the A/D conversion) in accordance with clock signals from the image pickup control unit 108. The digital signals resulting from the A/D conversion are combined in the image pickup control unit 108 and are transferred to the information processing apparatus 101 as digital image data.

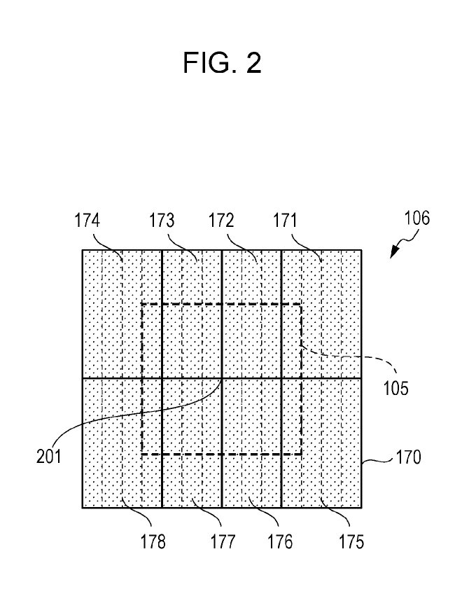

An allocated area, which is part of the image pickup area in the image sensor 106, is allocated to each of the A/D converters 151 to 158. The signals read out from the pixels in the image sensor 106 are subjected to the A/D conversion for every allocated area allocated to the A/D converter. The allocation to the A/D converters will be described in detail below with reference to FIG. 2.

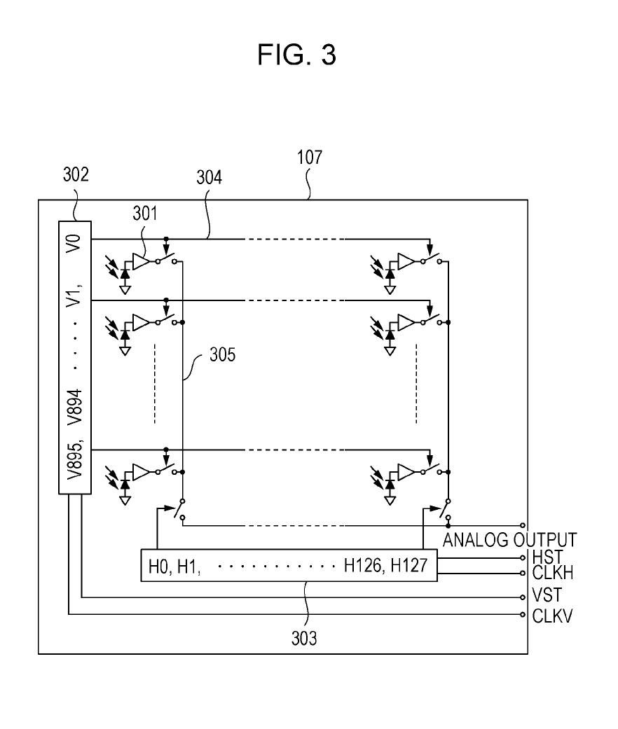

The image pickup control unit 108 is a control unit for the image pickup apparatus 100. For example, the image pickup control unit 108 controls, for example, the timing of driving of and power supply to each pixel circuit in the image sensor 106, a vertical shift register 302, and a horizontal shift register 303. The vertical shift register 302 and the horizontal shift register 303 will be described below with reference to FIG. 3. The image pickup control unit 108 also controls, for example, the timing of driving of and power supply to the analog multiplexers 131 to 138, the amplifiers 141 to 148, and the A/D converters 151 to 158.

The image pickup control unit 108 is capable of selectively performing control (first control) for driving the circuits in an 11-inch mode and control (second control for driving the circuits in a 6-inch mode. In the 11-inch mode, the entire image pickup area (a first area) of about 11 inches square in the image sensor 106 is irradiated with the radiation. Specifically, the image pickup control unit 108 performs the control (the first control) in which the outputs from the pixels in the entire image pickup area are acquired to generate image data and the image data is transferred to the information processing apparatus 101.

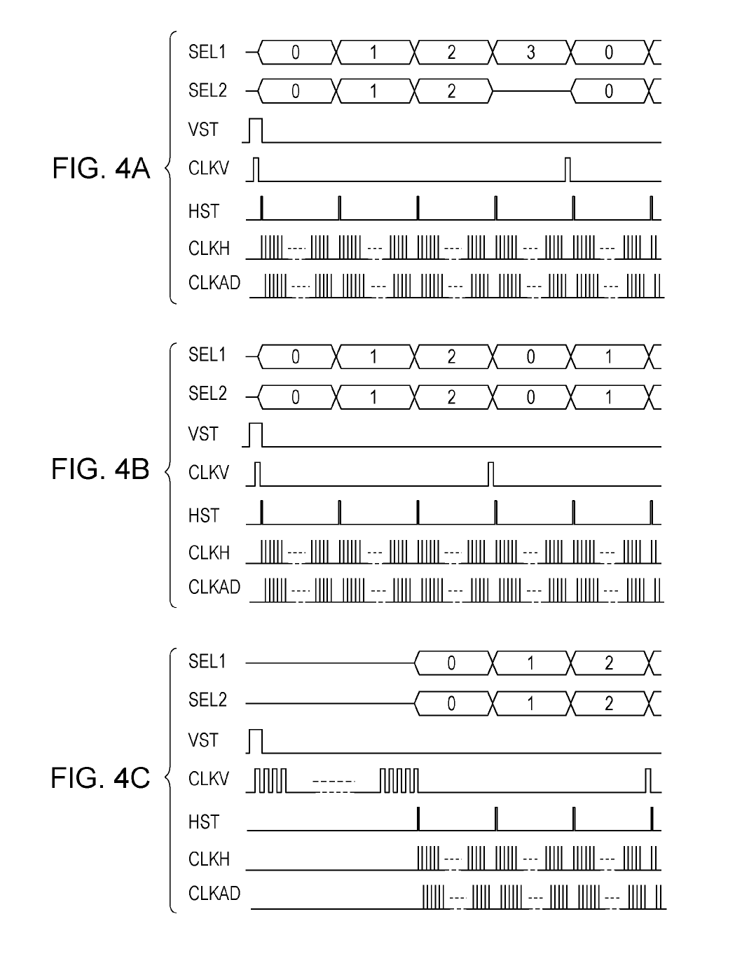

In contrast, in the 6-inch mode, an irradiation field of the radiation is limited to a partial area 105 that is included in the first area and that is about 6.3 inches square. The image pickup control unit 108 performs the control (the second control) in which analog signals are read out from the pixels in the partial area 105 (a second area) to generate image data and the image data is transferred to the information processing apparatus 101. The process of reading out signals from the pixels in the 11-inch mode and the 6-inch mode will be described below with reference to FIGS. 3 and 4.

FIG. 2 is a diagram for describing the allocation of the A/D converters 151 to 158 to the image sensor 106. An image pickup area 170 and allocated areas 171 to 178 allocated to the A/D converters 151 to 158, respectively, in the image sensor 106 are illustrated in FIG. 2.

Each of the allocated areas 171 to 178 is a small area resulting from division of the image pickup area 170. The signals from the pixels arranged in each allocated area are processed by the A/D converter to which the allocated area is allocated. For example, the A/D converter 151 performs the A/D conversion to the analog signals from the pixels arranged in the allocated area 171.

The allocated areas 171 to 178 are set so that the allocated areas close to a center position 201 of the partial area 105 are made small and the allocated areas far from the center position 201 are made large. In the allocation in FIG. 2, the allocated areas 171, 174, 175, and 178 correspond to four rectangular semiconductor substrates while the allocated areas 172, 173, 176, and 177 correspond to three rectangular semiconductor substrates, which are smaller than the allocated areas 171, 174, 175, and 178. Since the allocated areas are defined in units of substrates and each A/D converter is connected to different substrates, it is possible to simplify the control and the mounting.

Since the A/D converters having larger allocated areas are connected to the pixels of a larger number, the analog signals of a larger number are processed by the A/D converters. In contrast, the A/D converters having smaller allocated areas are connected to the pixels of a smaller number and the number of analog signals processed by the A/D converters is relatively small. Since the processing time for the A/D conversion is increased with the increasing number of signals to be processed, it is desirable to distribute the readout area to as many A/D converters as possible and to reduce the number of signals to be processed by each A/D converter as much as possible. Since the many small allocated areas are arranged near the partial area 105 in the present embodiment, it is possible to perform the A/D conversion of the partial area 105 in a distributed manner.

The readout range can be limited to the partial area 105 to process the partial area 105 with the processing load distributed to the many A/D converters.

In general, the concurrent processing of the analog signals from a certain area by multiple A/D converters can be most efficiently performed in a case in which the area is evenly allocated to the A/D converters. Accordingly, evenly allocating the entire image pickup area 170 in the image sensor 106 to the A/D converters allows the entire image pickup area 170 (the first area) to be most efficiently processed. However, the image pickup area 170 is not evenly allocated to the A/D converters and the allocated areas near the center position 201 are made small in the present embodiment.

Although the efficiency of the A/D conversion of the entire image pickup area 170 is reduced because of the above allocation manner in the present embodiment, it is possible to improve the efficiency of the A/D conversion by limiting the readout range to the partial area, compared with the uniform allocation.

In order to optimize the efficiency of the A/D conversion in the partial area 105, it may be desirable that the allocated areas 171, 174, 175, and 178 correspond to five rectangular semiconductor substrates and the allocated area 172, 173, 176, and 177 correspond to two rectangular semiconductor substrates. However, making the allocated areas near the center position 201 too small in this manner causes the processing time of the A/D converters having the allocated areas far from the center position 201 to be increased and the efficiency can possibly unallowably decreased in the A/D conversion of the entire image pickup area 170. Accordingly, the size of each allocated area is set so that the efficiency in the readout of the entire image pickup area 170 and the efficiency in the readout of the limited partial area are adapted to the specifications that are required and the transfer efficiency.

Although the partial area 105 is a central portion of the image pickup area 170 and the center position 201 is also the center position of the image sensor 106 or the image pickup area 170 in the examples in FIG. 1 and FIG. 2, the center position 201 may not be the center position thereof. Specifically, the allocated areas should be arranged such that the allocated areas near a certain position X included in the partial area 105, which is the limited readout range, are made small and the allocated areas far from the certain position X are made large.

When an X-ray tube having one focus is used as the radiation source 104, an anti-scatter grid having a focus is used with the image sensor 106. In this case, the center of the irradiation field of the radiation radiated from the radiation source 104 is required to be the center of the anti-scatter grid. In the case of the image pickup apparatus used with such a radiation source having one focus, the above certain position X is set to the focus position of the anti-scatter grid in the A/D conversion area in the image sensor 106. The allocated areas are arranged such that the allocated areas are made smaller with the decreasing distance to the certain position.

When a multi radiation source having multiple focuses in which multiple radiation sources are aligned linearly or in an array pattern is used, the above certain position X may be set to an arbitrary position but desirably substantially coincides with the center of the image sensor 106.

FIG. 3 illustrates an example of the configuration of the rectangular semiconductor substrate 107 in detail. Referring to FIG. 3, the pixels each including the photoelectric conversion element and a pixel amplifier 301 are arranged on the rectangular semiconductor substrate 107 in a two-dimensional matrix pattern. The vertical shift register 302 and the horizontal shift register 303 are provided as readout control circuits.

A row selection line 304 is a signal transmission line through which signals used for selecting the pixels arranged in the matrix pattern for every row are transmitted. A column signal line 305 is a signal transmission line through which analog signals from the pixels are externally read out from the image sensor 106, and the signals from the pixels selected by the row selection line 304 are transmitted through the column signal line 305. A vertical start signal VST is a start signal for the vertical shift register 302. A vertical clock CLKV is a shift clock for the vertical shift register 302 included in the rectangular semiconductor substrate. A combination of the vertical start signal VST and the vertical clock CLKV activates the vertically first row selection line 304 of the vertical shift register 302. Activation and deactivation of the row selection lines 304 are sequentially vertically switched in synchronization with the vertical clock CLKV to switch the pixels to be read out for every row.

A horizontal start signal HST is a start signal for the horizontal shift register 303. A horizontal clock CLKH is a shift clock for the horizontal shift register 303 included in the rectangular semiconductor substrate 107. A combination of the horizontal start signal HST and the horizontal clock CLKH activates the horizontally first column signal line 305 of the horizontal shift register 303. Activation and deactivation of the column signal lines 305 are sequentially horizontally switched in synchronization with the horizontal clock CLKH to sequentially supply the pixels in one line on the rectangular semiconductor substrate to an analog output terminal. The analog signals to be read out from the pixels are switched for every column in the above manner.

The image pickup control unit 108 supplies the vertical start signal VST and the vertical clock CLKV to the vertical shift register 302 through an external terminal (not shown). In addition, the image pickup control unit 108 supplies the horizontal start signal HST and the horizontal clock CLKH to the horizontal shift register 303 via the external terminal. An output Vn of the vertical shift register 302 is supplied to the pixels through the row selection line 304 in accordance with the above signals. An output Hn of the horizontal shift register 303 is supplied to the column signal line 305.

The output line for the pixels in the k-th horizontal line is activated in response to the k-th vertical clock CLKV and the output line for the pixels in the 1-th vertical line is activated in response to the 1-th horizontal clock CLKH. As a result, the analog signal from the pixel arranged at a position (k,l) is supplied to an analog output line. Each A/D converter is connected to at least one column signal line via the analog multiplexer and the amplifier to read the analog signals from the connected pixels.

The processing in the radiation imaging system 1 having the above configuration will now be described.

The image pickup control unit 108 sets an irradiation range in accordance with each mode in synchronization with the radiation generating apparatus 103 via the information processing apparatus 101. An irradiation range is where the radiation ray goes through. According to the setting by the image pickup control unit 108, the irradiation range is changed by control of a diaphragm for the radiation ray source or, for a radiation ray source with multiple focal points, control of the irradiation from each focal point.

The selection of a photographing mode by the image pickup control unit 108 is performed in response to an instruction from the information processing apparatus 101. For example, an operator inputs the photographing mode into the information processing apparatus 101 with a user interface including a mouse and/or a keyboard and a display. Alternatively, the information processing apparatus 101 automatically determines the photographing mode in accordance with the photographing region or the symptom of the object supplied from an external server apparatus or the like.

The information processing apparatus 101 instructs the photographing mode to the image pickup apparatus 100 and the radiation generating apparatus 103, and the image pickup control unit 108 in the image pickup apparatus 100 selects the photographing mode. In another example, the information processing apparatus 101 supplies the irradiation field of the radiation or the size of an image to be photographed to the image pickup control unit 108. Since life size (1× magnification) images are used for diagnosis in the medical field in principle, the size of an image is substantially equal to the size of the irradiation field.

When the size of the irradiation field or the image corresponds to the entire image pickup area, the image pickup control unit 108 performs the control (the first control) in which the image pickup control unit 108 reads out an analog signal from each pixel in the entire image pickup area (the first area), generates an image, and externally transfers the image.

When the size of the irradiation field or the image corresponds to the partial area in the image sensor 106, the image pickup control unit 108 performs the control (the second control) in which the image pickup control unit 108 reads out an analog signal from each pixel in the partial area (the second area), generates an image, and externally transfers the image.

Both in the 11-inch mode and the 6-inch mode, all the A/D converters 151 to 158 operate to perform the readout from the irradiation area. However, since the irradiation field is limited in the 6-inch mode, only one rectangular semiconductor substrate near the center portion has effective image information in each of the A/D conversion areas at the four corners. Accordingly, it is not necessary for the A/D converters 151, 154, 155, and 158 to perform the A/D conversion for the entire A/D conversion area. As described below, only three rectangular semiconductor substrates near the center portion are made targets for the readout and the A/D conversion in the 6-inch mode.

The throughput of the image sensor 106 is determined by a larger value, among the sum of the A/D conversion time and a reset time and the transfer time. The value of the throughput is a maximum value of the frame rate in the movie recording.

Provided that one side of the readout range decreases to 4/7, the A/D conversion time in the 6-inch mode deceases to about 3/7. In contrast, provided that the size of the central A/D conversion areas is the same as that of the peripheral A/D conversion areas, the A/D conversion time decreases to about 4/7. Consequently, the A/D conversion time in the present embodiment is smaller than that in the case in which the size of the central A/D conversion areas is the same as that of the peripheral A/D conversion areas.

The value in the present embodiment is larger than 16/49≈2.28/7, which is an approximate reduction rate of image data, and the effect of limiting the readout range is increased.

As described above, in the present embodiment, the central portion of the image sensor 106 is processed by the A/D converters having a smaller number of pixels that are connected while the four-corner areas including the four apices of the image sensor 106 are processed by the A/D converters having a larger number of pixels that are connected. Accordingly, it is possible to largely decrease the A/D conversion time when the readout range is limited to an area near the central portion.

It is possible to largely increase the throughput in photographing at a narrow angle of field with the irradiation field being narrowed down while the throughput in the readout from the entire image pickup area is restricted to an allowable range. When the readout range is limited to a certain partial area, instead of the central portion, the A/D conversion areas near the center of the certain partial area are made smaller than the A/D conversion areas at the four corners. It is possible to largely increase the throughput when the readout range is limited to the central portion, as described above.

Examples of the readout of image data in the 11-inch mode and the 6-inch mode will now be described with reference to time charts in FIGS. 4A to 4C.

Signals SEL1 and SEL2 are each used to select a substrate from which image data is read out from the substrates to which the analog multiplexers 131 to 138 are connected. The outer analog multiplexers 131, 134, 135, and 138 switch the analog signals from the four rectangular semiconductor substrates under the control with the signal SEL1. The central analog multiplexers 132, 133, 136, and 137 switch the analog signals from the three rectangular semiconductor substrates under the control with the signal SEL2.

Numbers 0 to 3 indicated on input terminals of each of the analog multiplexers 131 to 138 have one-to-one correspondence with the numerical values indicated in the signals SEL1 and SEL2 in the time charts. For example, if the outputs from the signals SEL1 and SEL2 are “0”, an input of “0” of the analog multiplexer is selected and the selected input is supplied to the next amplifier. The inputs into the analog multiplexers 134 and 135 are configured so that the output from the outermost rectangular semiconductor substrate is selected when the output of the signal SEL1 is “3”.

When the vertical clock CLKV rises in a state in which the vertical start signal VST is set to “H”, a circuit in the vertical shift register 302 is reset. Then, “H” is supplied to the output V0 of the vertical shift register 302 and is supplied to the pixels through the row selection line 304. This activates the output from the pixels in one horizontal line.

When the horizontal clock CLKH rises in a state in which the horizontal start signal HST is set to “H”, a circuit in the horizontal shift register 303 is reset. Then, “H” is supplied to the output HO of the horizontal shift register 303, the output from the pixels in one vertical line is activated, and the output from the pixels are supplied to the column signal line 305. Among the pixels on the activated one horizontal line, the output from the pixel selected with the output HO is supplied to the analog output terminal. The pulses of the horizontal clock CLKH are sequentially received and the output of “H” from the horizontal shift register 303 is sequentially shifted from HO. When the output of “H” from the horizontal shift register 303 is shifted to H127, the readout from one line is completed.

Next, the vertical clock CLKV is received and the output of “H” from the vertical shift register 302 is switched to V1. Then, the readout from this horizontal line is performed. The selection of each row and the readout operation of the pixels are repeated to perform the readout of image data from the pixels on the rectangular semiconductor substrate 107.

The outputs from the pixels on the rectangular semiconductor substrate 107 are sequentially supplied to the external analog output terminal in synchronization with the horizontal clock CLKH. The A/D converter performs the A/D conversion in response to an A/D conversion clock CLKAD synchronized with the horizontal clock CLKH.

The A/D converter performs the A/D conversion to one horizontal line in the A/D conversion area in synchronization with the switching of the input into the analog multiplexer. The A/D converter vertically repeats the A/D conversion from the outer lines to the central lines.

This processing will now be described, taking the A/D conversion area composed of the four rectangular semiconductor substrates at the upper left corner in FIG. 1 as an example. The signals are read out from the pixels on one horizontal line closest to the analog multiplexer 134 across the rectangular semiconductor substrates and the readout signals are subjected to the A/D conversion by the A/D converter 154.

When the readout of the signals from the pixels on one horizontal line is completed, the signals are read out from the pixels on the next horizontal line and the readout signals are subjected to the A/D conversion. This processing is performed in the entire A/D conversion area. When the A/D converter completes the processing of all the pixels arranged in one A/D conversion area composed of three or four rectangular semiconductor substrates, the A/D conversion is completed. Then, the image sensor 106 performs the reset operation and moves to the next readout cycle. Image data is generated from the digital signal concurrently with the reset operation and the generated image data is transferred to the information processing apparatus 101.

FIG. 4A is a time chart indicating an example of the readout control (the first control) in the 11-inch mode. Referring to FIG. 4A, in the readout in the 11-inch mode, the signals are read out from the pixels on one line of each of the eight A/D conversion areas in the order of 0, 1, and 2. When the output of the signal SEL1 is “3”, the signals are read out from the pixels in rectangular semiconductor substrates 161 to 164 at both ends, illustrated in FIG. 1, as valid data. During the readout of the signals from the pixels on the rectangular semiconductor substrates 161 to 164, the image pickup control unit 108 ignores the outputs from the A/D converters 151, 154, 155, and 158.

The image pickup control unit 108 combines only the valid pieces of data to generate data on each line of the image sensor 106. The image pickup control unit 108 compiles the pieces of data on each line to generate image data and supplies the generated image data to the information processing apparatus 101.

FIG. 4B is a time chart indicating an example of the readout control (the second control) in the 6-inch mode. The 6-inch mode differs from the 11-inch mode in that the signals are not read out from the pixels in the outermost rectangular semiconductor substrates and that the readout of the analog signals from the pixels arranged in an upper-side portion and a lower-side portion outside the partial area is skipped.

In the present embodiment, all the A/D converters 151 to 158 perform the A/D conversion to three rectangular semiconductor substrates. Accordingly, the same number of pixels is processed by each A/D converter. The conversion areas of the A/D converters 151, 154, 155, and 158 at the four corners each include two substrates outside the irradiation area, which are adjacent to one substrate in the irradiation area and which are continuously tiled. However, this does not make a difference in the size of the A/D conversion areas and it takes the same A/D conversion time as in the case in which the substrates outside the irradiation field are not subjected to the A/D conversion. In addition, it is possible to desirably simplify the driving in a manner described below.

Since the A/D converters at the four corners process only three rectangular semiconductor substrates, the image pickup control unit 108 causes the analog multiplexers at the four corners not to select the outermost substrates. Accordingly, the image pickup control unit 108 performs the control such that the signals are not read out from the pixels on the peripheral rectangular semiconductor substrates 161 to 164 far from the center. Since the image pickup apparatus 100 is configured so as to select the outputs from the outermost rectangular semiconductor substrates 161 to 164 when the output of the signal SEL1 is “3”, non-selection of “3” of the signal SEL1 causes the outermost substrates to be excluded from the target of the A/D conversion.

Since the uniform driving is achieved in the image pickup apparatus 100 by causing the A/D converters at the four corners to perform the A/D conversion to the inner three substrates in the above manner, it is possible to simplify the control. In addition, also when the A/D converters at the four corners perform the A/D conversion to the inner three substrates, there is no difference in the A/D conversion time from the case in which only one inner substrate is subjected to the A/D conversion. Accordingly, the effect on the throughput is small.

In order to reduce the readout time, the readout of the signals from the pixels in an upper-side portion and a lower-side portion outside the irradiation field is skipped. The A/D converters 152, 153, 156, and 157 each skip the readout of the signals from the pixels in an upper-side portion and a lower-side portion outside the irradiation field, each having a length of 384 pixels and a width of 384 pixels, and each perform the A/D conversion to an area having a length of 512 pixels and a width of 384 pixels within the irradiation field. On the 384 pixel columns outside the partial area 105 (outside the second area), the pulses of the vertical clock CLKV are continuously output to perform only the shift of the vertical shift register 302. The horizontal start signal HST and the horizontal clock CLKH are caused not to operate. In the example in FIG. 4B, the readout of the signals from the pixels is skipped during a period from the vertical start signal VST to the horizontal start signal HST. Since the readout of images from unnecessary pixels is not performed in the skip of the readout of the signals from the pixels, the processing time per one line is shorter than that in the readout of all the lines.

The A/D converters 151, 154, 155, and 158 also each skip the readout of the signals from the pixels in an upper-side portion and a lower-side portion outside the irradiation field, like the A/D converters 152, 153, 156, and 157. Accordingly, the A/D conversion can be performed to an area including the partial area 105 in the 6-inch mode. Then, the image pickup control unit 108 combines the digital signals subjected to the A/D conversion to generate data on one line. The image pickup control unit 108 compiles the pieces of data on one line, which is sequentially subjected to the A/D conversion and is combined, to generate image data and supplies the generated image data to the information processing apparatus 101.

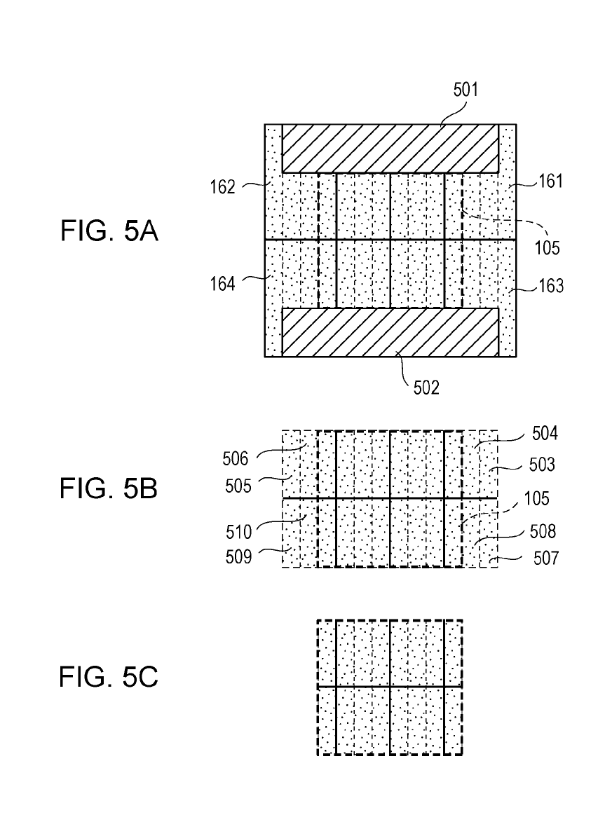

The image data read out in the 6-inch mode includes data on an image area outside the irradiation field. Accordingly, a process of cutting out a necessary area from the readout image and transferring the image resulting from the cutout to the information processing apparatus 101 is performed. FIGS. 5A to 5C include diagrams illustrating an example of how an image is cut out in the 6-inch mode. FIG. 5A is a diagram illustrating the readout of signals from the pixels in the entire image pickup area in the image sensor 106 in the 11-inch mode. The partial area 105 denoted by a broken line is an irradiation image area in the 6-inch mode. In areas 501 and 502, the readout of the signals from the pixels is not performed due to the skipping. Image data is read out from the pixels in an area illustrated in FIG. 5B by the above readout method. The readout image data includes areas 503 to 510 outside the partial area 105 in the 6-inch mode. Since the areas 503 to 510 are not necessary as the image, the cutout of the image is performed in the transfer to the information processing apparatus 101 to transfer only an area illustrated in FIG. 5C. The cutout of an image is performed by accessing part of the image in FIG. 5B decomposed in a frame memory.

An example of how to calculate the throughput in the image pickup apparatus 100 will now be described. The rectangular semiconductor substrate 107 has a strip shape having a width of about 20 mm and a length of about 140 mm. A case in which 128 pixels are horizontally arranged and 896 pixels are vertically arranged at intervals of 160 μm in the rectangular semiconductor substrate 107 is exemplified here.

At the beginning, the transfer rate will be described. In the 11-inch mode, since the number of pixels in the horizontal direction is 128×14=1,792 and the number of pixels in the vertical direction is 896×2=1,792, the total number of pixels is 3,211,264. In the 6-inch mode, since the number of pixels in the horizontal direction is 128×8=1,024 and the number of pixels in the vertical direction is 512×2=1,024, the total number of pixels is 1,048,576. When 16-bit data is output from the A/D converter, one frame includes 6,422,528 bytes in the 11-inch mode and includes 2,097,152 bytes in the 6-inch mode.

When an image transfer interface 109 illustrated in FIG. 1 has a maximum transfer rate of about two gigabits per second, the maximum transfer rate is about 200 megabytes per second in consideration of eight-bit/ten-bit encoding. Accordingly, it is possible to transfer an image at a maximum of about 31 frames per second in the 11-inch mode and at a maximum of about 95 frames per second in the 6-inch mode.

Next, the A/D conversion time and the throughput in the 11-inch mode will be described. It is assumed here that the clock frequency used in the readout from the rectangular semiconductor substrates and the conversion in the A/D converters is 20 MHz, a flyback time at which the line is switched in the A/D conversion is one microsecond, and an input switch time of the analog multiplexers is one microsecond. It is also assumed here that the time required for reset driving of the photoelectric conversion on the rectangular semiconductor substrates is one millisecond.

The time required to read out the signals from 512 pixels on one line across the four rectangular semiconductor substrates at 20 MHz and perform the A/D conversion to the readout signals under the above conditions is 25.6 microseconds. Addition of the switching time, four microseconds, in the analog multiplexers corresponding to the four rectangular semiconductor substrates and the flyback time, one microsecond, to 25.6 microseconds results in 30.6 microseconds. When the readout scanning is vertically performed 896 times, addition of the time required for reset driving for every frame, one millisecond, to the above value results in about 28.4 milliseconds. This is the time required for the A/D conversion of the area corresponding to the four rectangular semiconductor substrates, which has 512 pixels in the horizontal direction and 896 pixels in the vertical direction, with one A/D converter.

Similarly, the time required to read out the signals from 384 pixels on one line across the three rectangular semiconductor substrates at 20 MHz and perform the A/D conversion to the readout signals is 19.2 microseconds. Addition of the switching time, three microseconds, in the analog multiplexers corresponding to the three rectangular semiconductor substrates and the flyback time, one microsecond, to 19.2 microseconds results in 23.2 microseconds. When the readout scanning is vertically performed 896 times, addition of the time required for reset driving for every frame, one millisecond, to the above value results in about 21.8 milliseconds. This is the time required for the A/D conversion of the area corresponding to the three rectangular semiconductor substrates, which has 384 pixels in the horizontal direction and 896 pixels in the vertical direction, with one A/D converter.

Since the image pickup apparatus 100 includes the multiple A/D converters and concurrently performs the A/D conversion with the multiple A/D converters, the factor determining the signal readout time is the A/D converter having the largest number of pixels to be processed. In the 11-inch mode, the A/D conversion time in the area corresponding to the four rectangular semiconductor substrates is 28.4 milliseconds and the readout rate from the area is about 35.2 times per second. The A/D conversion time in the area corresponding to the three rectangular semiconductor substrates is 21.8 milliseconds and the readout rate from the area is about 45.9 times per second. The maximum frame rate in the 11-inch mode is about 35.2 frames per second because it depends on the readout rate from the area corresponding to the four rectangular semiconductor substrates.

As described above, the maximum data transfer rate of the image transfer interface 109 in the 11-inch mode is about 31 frames per second. Accordingly, the maximum frame rate in the radiation imaging system 1 in the 11-inch mode is about 31 frames per second, which depends on the transfer capability of the image transfer interface 109.

Next, the A/D conversion time and the throughput in the 6-inch mode will be described. Provided that the skipping time of the readout from the pixels in one line is one microsecond, which is equal to the flyback time of the line, the time required for the skip of the readout of the signals from the pixels is 384 microseconds.

It is assumed in the 6-inch mode, as in the 11-inch mode, that the conversion clock frequency in the A/D converters is 20 MHz, the flyback time at which the line is switched in the A/D conversion is one microsecond, and the input switch time of the analog multiplexers is one microsecond. It is also assumed in the 6-inch mode that the time required for reset driving of the photoelectric conversion on the rectangular semiconductor substrates is one millisecond.

The time required to read out the signals from 384 pixels on one line across the three rectangular semiconductor substrates at 20 MHz and perform the A/D conversion to the readout signals under the above conditions is 19.2 microseconds. Addition of the switching time, three microseconds, in the analog multiplexers corresponding to the three rectangular semiconductor substrates and the flyback time, one microsecond, to 19.2 microseconds results in 23.2 microseconds. When the readout scanning is vertically performed 512 times, addition of the time required for the skip of the readout, 384 microseconds, and the time required for reset driving for every frame, one millisecond, to the above value results in about 13.3 milliseconds. This is the time required for the A/D conversion of the area corresponding to the three rectangular semiconductor substrates, which has 384 pixels in the horizontal direction and 896 pixels in the vertical direction, with one A/D converter.

Since all the A/D converters perform the A/D conversion to the A/D conversion areas having the same size, the A/D conversion time in the partial area 105 in the 6-inch mode is equal to one A/D conversion time. Accordingly, the A/D conversion time is about 13.3 milliseconds and the readout rate from this area is about 75.4 times per second.

As described above, the maximum transfer capability of the image transfer interface 109 in the 6-inch mode is about 95 frames per second and the readout rate is about 75.4 frames per second. Consequently, the maximum frame rate in the radiation imaging system in the 6-inch mode is about 75.4 frames per second, which depends on the processing in the A/D converters.

In the first embodiment, in the 11-inch mode, the transfer capability of the image transfer interface 109 is used to the maximum level, which is 30 frames per second. In contrast, in the 6-inch mode, it is possible to realize the movie recording at a high frame rate higher than 60 frames per second and at a high definition. It is sufficient to achieve a frame rate of 30 frames per second in the general movie recording. However, it is required to achieve a frame rate higher than 60 frames per second in a high-definition mode without a binning process in recent years. For example, such a high frame rate is required in a case in which an image of a moving organ, such as a heart, is captured at a high definition with a guide wire of a fine catheter in the movie recording at a narrow angle of field at which the irradiation area is narrowed. The photographing modes including the 11-inch mode and the 6-inch mode in the present embodiment are very useful because they meet the above request. The frame rate may possibly be determined by the A/D converters in any of the photographing modes with the increasing number of pixels in the image sensor and the increasing transfer speed. In such a case, limiting the readout range allows the effect of the improvement of the throughput to be increased.

In another example of driving, the skip of the readout of the signals from the pixels in an upper-side portion and a lower-side portion outside the irradiation field is not performed. As illustrated in FIG. 4C, the signal SEL1 has the same output pattern as that of the signal SEL2, the readout driving is simplified, and the time to read out the signals from the pixels on one line decreases to ¾. In addition, since the driving is performed in the same manner as in the 11-inch mode except that the signal SEL1 does not output “3”, the readout driving is further simplified.

In another example of driving, the signals from three outer rectangular semiconductor substrates are not subjected to the A/D conversion because the three outer rectangular semiconductor substrates are outside the irradiation field. Since the cutout of the image to be transferred after the A/D conversion is not necessary in this case, it is possible to further improve the throughput.

### Second Embodiment

Although the rectangular semiconductor substrates are tiled in a matrix pattern of 14 columns and two rows in the first embodiment, as illustrated in FIG. 1, the numbers of rows and columns in the matrix pattern are not specifically restricted as long as the A/D conversion areas near the center of the limited readout range in an image sensor 606 are smaller than the A/D conversion areas including the four corners.

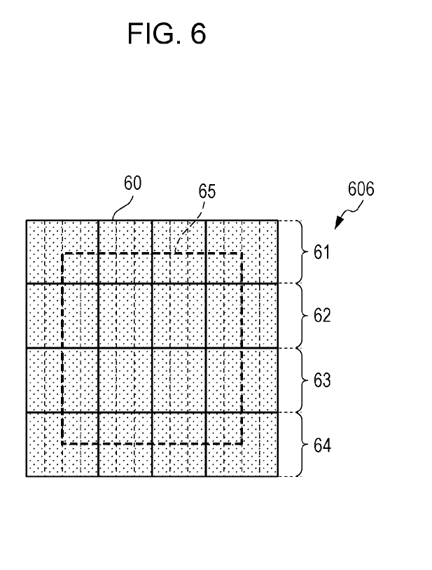

FIG. 6 illustrates a flat panel sensor in which rectangular semiconductor substrates are tiled in a matrix pattern of 14 columns and four rows according to a second embodiment. In the flat panel sensor in FIG. 6, the rectangular semiconductor substrates tiled in one row are divided into A/D conversion areas having four rectangular semiconductor substrates, three rectangular semiconductor substrates, three rectangular semiconductor substrates, and four rectangular semiconductor substrates from the left side in FIG. 6.

A control circuit (not shown) in the image sensor 606 is connected to the rectangular semiconductor substrates via signal lines extending from the upper ends of the rectangular semiconductor substrates tiled on a row 61. Signal lines extend from the lower ends of the rectangular semiconductor substrates tiled on a row 64. In the rectangular semiconductor substrates tiled on a row 62, signal lines extend from the rear face of the image sensor 606 at the boundary between the row 61 and the row 62. In the rectangular semiconductor substrates tiled on a row 63, signal lines extend from the rear face of the image sensor 606 at the boundary between the row 63 and the row 64. Flat flexible cables (not shown) of about 50 micrometers are mounted at the boundaries and are bent at right angles at ends of the rectangular semiconductor substrates. The signal lines extend from the flat flexible cables bent at right angles. The central A/D conversion areas are made smaller than the A/D conversion areas at the four corners in the above manner.

The readout range can be narrowed down from an entire area 60 (a first area) in the image sensor 606 to a central partial area 65 (a second area) to greatly improve the throughput, as in the first embodiment.

### Third Embodiment

Three or more photographing modes including the 11-inch mode and the 6-inch mode can be executed in a third embodiment. Specifically, a third photographing mode can be executed in the third embodiment, in which an irradiation field (a first area) narrower than the area in the 11-inch mode by 128 pixels from the left and right ends of the area is set for photographing. The number of the rectangular semiconductor substrates in the peripheral A/D conversion areas may be switched from four to three. For example, since the readout rate is determined by the A/D conversion time of 384 pixels×512 pixels corresponding to the three rectangular semiconductor substrates in this case, it is possible to increase the readout rate in the flat panel sensor.

In another example, an arbitrary partial area may be set as the readout area in response to an instruction from the information processing apparatus 101. In this case, an instruction to set an arbitrary partial area in the image pickup area 170 is issued from the information processing apparatus 101. The image pickup control unit 108 determines which rectangular semiconductor substrate the signals are not read out from and which row in the rectangular semiconductor substrates the readout of the signals is skipped on in response to the above instruction. When the rectangular semiconductor substrates from which the signals are not read out exist, the SEL signals corresponding to the rectangular semiconductor substrates the readout of the signals from which is skipped are not transmitted to the analog multiplexers, as in the first embodiment. Also when the rows the readout of the signals from which is skipped exist, only the selection of the row selection line is performed, as in the first embodiment, and the selection of the column signal is not performed to skip the readout of the signals.

In the image pickup apparatus capable of the above control, the wiring between the analog multiplexers and the image sensor is set so that the allocated areas of some A/D converters are smaller than the allocated areas of the remaining A/D converters. Setting the wiring in the above manner and setting a partial area including part of the small allocated areas as the readout area allows the load to be distributed between as many A/D converters as possible for the A/D conversion. Accordingly, it is possible to reduce the A/D conversion time to improve the throughput.

### Fourth Embodiment

In a fourth embodiment, it is possible to perform control (second control) in which an irradiation field (a second area) narrower than the entire area (a first area) of the image sensor 106 by 128 pixels from the left and right ends of the first area is set for photographing. As in the first embodiment, it is also possible to perform the photographing control in the 11-inch mode (first control) and the photographing control in the 6-inch mode. In the photographing control, the rectangular semiconductor substrates that are not used may be turned off or the amplifiers in the pixel circuit may not be turned on, instead of turning off the rectangular semiconductor substrates. When the rectangular semiconductor substrates outside the irradiation area are turned off, low-level or high-impedance control signals are supplied to the corresponding rectangular semiconductor substrates. This allows power saving.

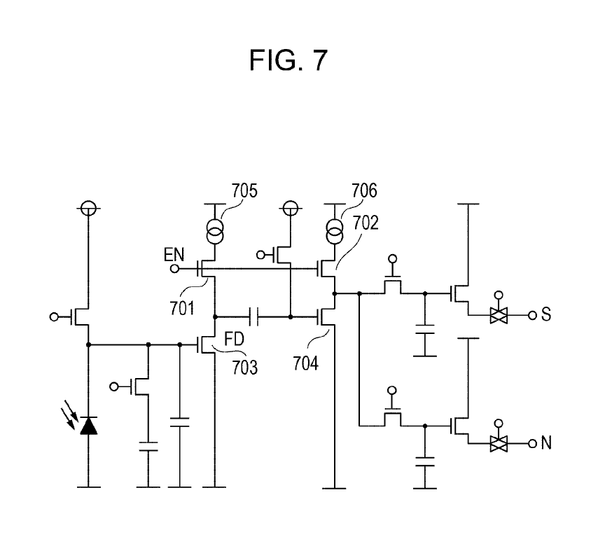

FIG. 7 illustrates one exemplary pixel circuit, among the pixel circuits two-dimensionally configured on the rectangular semiconductor substrate. A method of saving power by not operating the amplifiers in the pixel circuits, instead of turning off the rectangular semiconductor substrates, will now be described with reference to the pixel circuit in FIG. 7.

Referring to FIG. 7, a floating diffusion (FD) amplifier 703 is an amplifier metal oxide semiconductor (MOS) transistor operating as a source follower that performs charge/voltage conversion to the electric charge accumulated in a floating diffusion area. A selection element 701 is a selection MOS transistor operating the FD amplifier 703 in response to an EN signal. A pixel amplifier 704 is an amplifier MOS transistor operating as a source follower. A metal oxide semiconductor-field effect transistor (MOSFET) 702 is a selection MOS transistor operating the pixel amplifier 704 in response to the EN signal. The FD amplifier 703 and the pixel amplifier 704 are operated in response to the EN signal output from the image pickup control unit 108. As a result, a current of around 0.3 μA supplied from a constant current circuit 705 flows through the FD amplifier 703 and a current of around 0.3 μA supplied from a constant current circuit 706 flows through the pixel amplifier 704. The EN signal is set to an OFF state for the rectangular semiconductor substrates outside the irradiation field to cause the amplifiers in the pixel circuit not to operate. This results in power saving by a current of about 67 mA flowing through the FD amplifiers 703 and the pixel amplifiers 704 in the pixel circuits of a number equal to 114,688 (128 pixels×896 pixels=114,688) per rectangular semiconductor substrate. The power saving of a total of about 269 mA can be achieved.

The image pickup control unit 108 supplies power only to the amplifiers in the pixel circuits within the irradiation area. No power may be supplied to the pixel amplifiers in an area in which the signals are subjected to the A/D conversion as invalid data.

The power supply to the circuits that do not require the power can be stopped in the limitation of the readout range to reduce the power consumption.

### Fifth Embodiment

An example in which the present invention is applied to a flat panel sensor using a metal insulator semiconductor (MIS) photodiode is described in a fifth embodiment. In such a MIS sensor, an amorphous silicon film is provided on a large substrate made of glass and a photoelectric conversion element and a thin-film field effect transistor are concurrently formed on the amorphous silicon film.

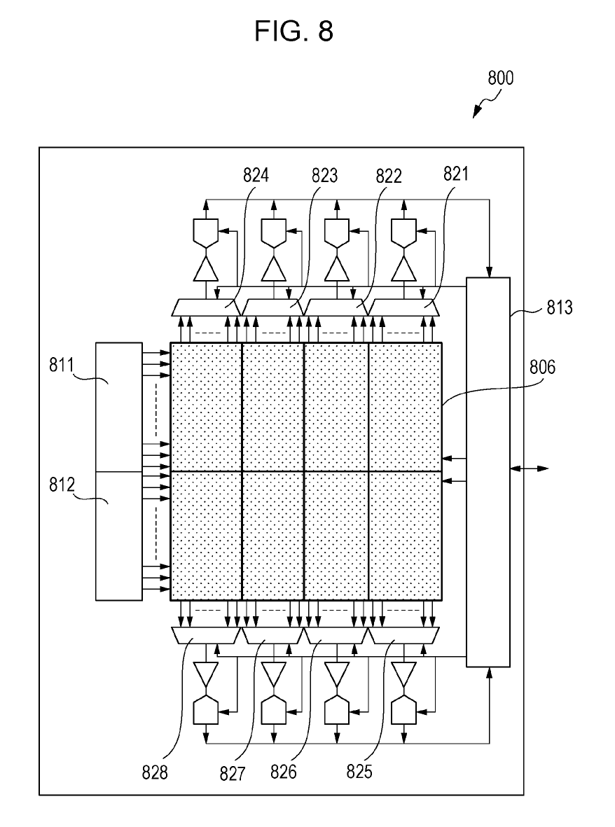

FIG. 8 illustrates an example of the configuration of an image pickup apparatus 800 using a MIS flat panel sensor. Referring to FIG. 8, an image pickup control unit 813 controls the image pickup apparatus 800. An image sensor 806 is a MIS image sensor. A vertical shift register and a horizontal shift register for the pixel readout are not provided on the substrate of the image sensor 806 and are provided outside the image sensor 806. Row selection lines in the image sensor 806 are connected to vertical shift registers 811 and 812 in a one-to-one correspondence manner.

Row selection signals are shifted from the upper end of the vertical shift register 811 toward a center portion thereof. Row selection signals are shifted from the lower end of the vertical shift register 812 to a center portion thereof. Analog multiplexers 821 to 828 each have a horizontal shift register function and analog signals output from each column in the image sensor 806 are connected to the analog multiplexers 821 to 828 in a one-to-one correspondence manner.

The areas allocated to the analog multiplexers 821, 824, 825, and 828 at the four corners are larger than the areas allocated to the central analog multiplexer 822, 823, 826, and 827. When the irradiation field and the readout range are limited, the readout speed is determined by the readout time from the central analog multiplexers having a small number of signals to be processed. Accordingly, the readout range can be limited to achieve the effects similar to the ones in the above embodiments.

The present invention may be applied to a flat panel sensor using a PIN photodiode. The scope of the present invention is not restricted by the configuration of the image sensor as long as the central A/D conversion areas in the image area in the image sensor are smaller than the A/D conversion areas including the four corners in the image area in the image sensor.

### Sixth Embodiment

In a sixth embodiment, switching elements are provided on each rectangular semiconductor substrate 907, instead of the analog multiplexers.

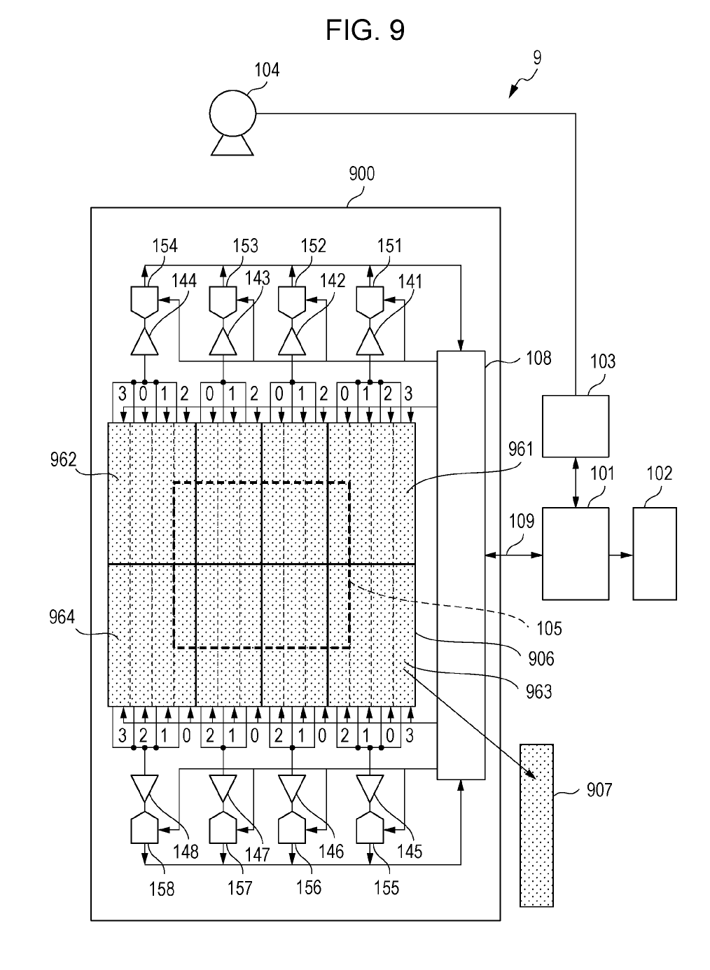

FIG. 9 illustrates an example of the configuration of a radiation imaging system 9 of the sixth embodiment. A description of the same components as in the first embodiment is omitted herein. In the sixth embodiment, the rectangular semiconductor substrates 907 are directly connected to the amplifiers not via the analog multiplexers in an image pickup apparatus 900. An analog switching element for switching between activation and deactivation of the analog output is provided on each rectangular semiconductor substrate 907.

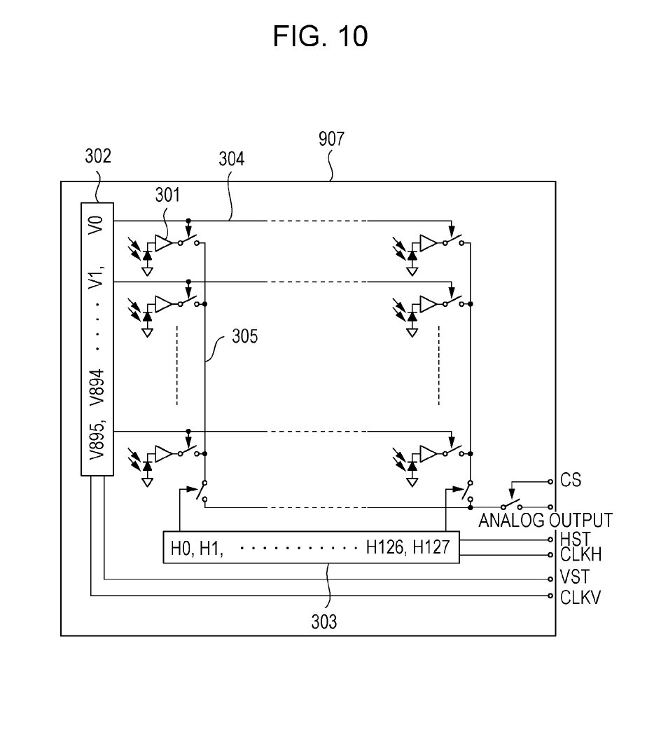

FIG. 10 illustrates an example of the configuration of the rectangular semiconductor substrate 907. A description of the same components as in the first embodiment is omitted herein. The image pickup control unit 108 controls the output from each rectangular semiconductor substrate 907 in response to a chip select signal CS. The analog output lines of the rectangular semiconductor substrates are collectively connected to the amplifiers, without the analog multiplexers.

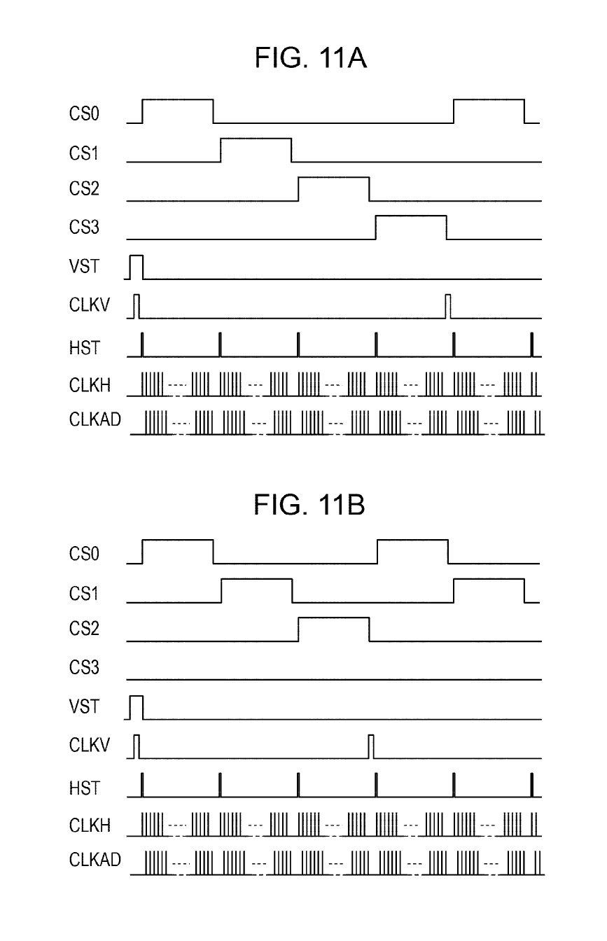

Examples of the readout of image data in the 11-inch mode and the 6-inch mode in the sixth embodiment will now be described with reference to time charts in FIGS. 11A and 11B. A description of the same components as in the first embodiment is omitted herein.

FIG. 11A is a time chart indicating an example of the readout control (the first control) in the 11-inch mode, in which the signals are read out from the entire image area (the first area) in an image sensor 906 in FIG. 9. FIG. 11B is a time chart indicating an example of the readout control (the second control) in the 6-inch mode, in which the image in the partial area 105 (the second area) is displayed.

Referring to FIGS. 11A and 11B, signals CS0 to CS3 are chip select signals used to control the output of the analog signals from the rectangular semiconductor substrates. Numbers allocated to the analog signals output from the rectangular semiconductor substrates in FIG. 9 have a one-to-one correspondence with the numeric characters of the chip select signals CS in the time charts.

For example, while the chip select signal CS0 is “H”, the analog output of the analog output signal number “0” from the rectangular semiconductor substrate is activated and is supplied to the next-stage amplifier. While the chip select signal CS1 is “H”, the analog output of the analog output signal number “1” from the rectangular semiconductor substrate is activated and is supplied to the next-stage amplifier. The chip select signal CS0 is connected to the rectangular semiconductor substrate having the analog output signal number “0.” The chip select signal CS1 is connected to the rectangular semiconductor substrate having the analog output signal number “1.” The chip select signal CS2 is connected to the rectangular semiconductor substrate having the analog output signal number “2.” The chip select signal CS3 is connected to the rectangular semiconductor substrate having the analog output signal number “3.”

The chip select signal CS3 is connected to the outermost rectangular semiconductor substrates. As illustrated in FIG. 11A, the signals are read out from the pixels on one line of each of the eight A/D conversion areas in the order of the analog signal numbers 0, 1, and 2. While the chip select signal CS3 is “H”, the signals are read out from the pixels on rectangular semiconductor substrates 961 to 964 at both ends of the image sensor 906. The readout pieces of data are sorted in the image pickup control unit 108 and are transferred to the information processing apparatus 101. In the 6-inch mode, since the chip select signals CS0 to CS2 are varied and the chip select signal CS3 is kept at “L”, as illustrated in FIG. 11B, the time required for the readout of the image data on one line decreases to ¾ of that in the 11-inch mode.

### OTHER EMBODIMENTS

In the above embodiments, the processing performed in one apparatus in the radiation imaging system may be distributed between multiple apparatuses. The processing integrated in one functional block may be distributed between multiple circuits or multiple functional blocks.

Although the example in which the readout range is limited to a central portion of the image sensor is described in the above embodiments, for example, the readout range may be limited to a certain partial area. The scope of the present invention is not limited to the above embodiments as long as the number of connected pixels of the A/D converters having the allocated areas near the center of the limited readout area is larger than that of the A/D converters having the allocated areas at the four corners.

As described above, the allocated areas near a certain position in the image pickup area are smaller than the allocated areas far from the certain position. Accordingly, the readout range can be limited to a partial area including the certain position to increase the number of the A/D converters between which the processing load is distributed. As a result, the limitation of the readout range allows the A/D conversion time to be decreased to greatly improve the throughput.

### COMPARATIVE EXAMPLES

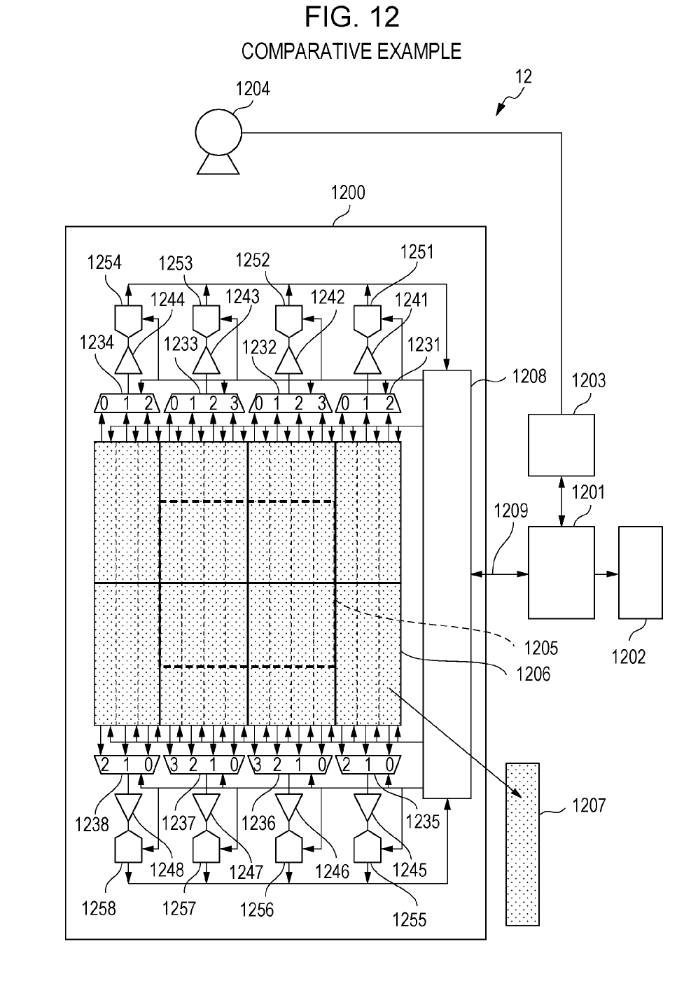

A radiation imaging system 12 as a comparative example will now be described with reference to FIG. 12. In an image pickup apparatus 1200 in the comparative example, pixels of a smaller number are connected to A/D converters at both ends and pixels of a larger number are connected to central A/D converters. The image pickup apparatus 1200 includes an information processing apparatus 1201, an image display apparatus 1202, a radiation generating apparatus 1203, a radiation source 1204, and multiple rectangular semiconductor substrates 1207, as in the above embodiments. A/D converters 1251 to 1258 are connected to an image sensor 1206 via analog multiplexers 1231 to 1238 and amplifiers 1241 to 1248, respectively. The comparative example differs from the embodiments in that the A/D converters 1251, 1254, 1255, and 1258 are connected to the three rectangular semiconductor substrates and the A/D converters 1252, 1253, 1256, and 1257 are connected to the four rectangular semiconductor substrates. This configuration simplifies the driving of the image pickup apparatus in the 11-inch mode and the driving of the image pickup apparatus in the 6-inch mode. One A/D converter is used for multiple rectangular semiconductor substrates, as in the embodiments, to decrease the number of the A/D converters that are used, thereby reducing the cost.

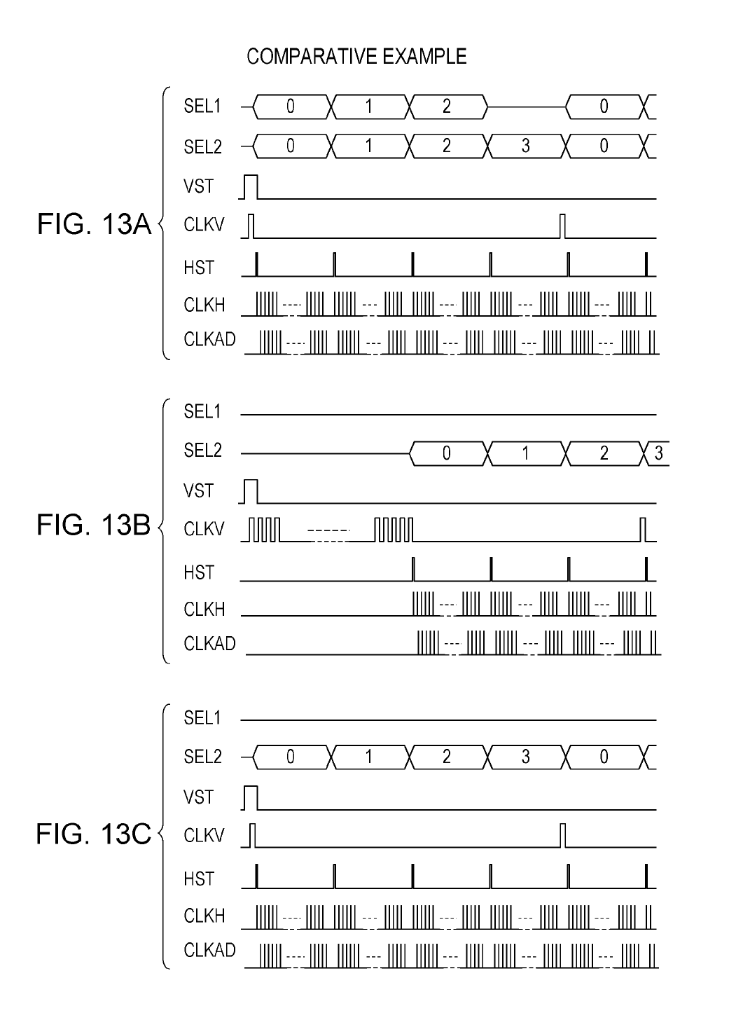

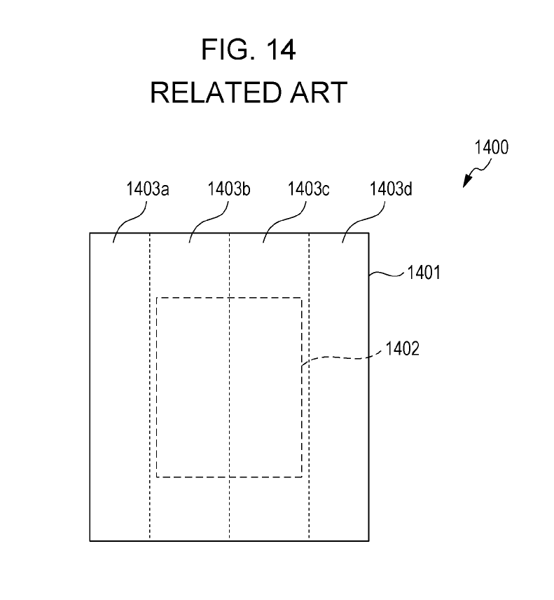

How the image pickup apparatus 1200 is driven will now be described with reference to time charts in FIGS. 13A to 13C. FIG. 13A is a time chart illustrating an example of the driving in the 11-inch mode. The image pickup apparatus 1200 differs from the image pickup apparatus 100 of the first embodiment in that the signal SEL1 of the first embodiment is used as the signal SEL2 and the signal SEL2 of the first embodiment is used as the signal SEL1. The comparative example is the same as the first embodiment except for the above difference.

FIG. 13B is a time chart illustrating an example of the driving in the 6-inch mode. In the example of the driving in FIG. 13B, the signals are not read out from an area outside an irradiation area 1205. Accordingly, the readout area is an area having a width of 1,024 pixels and a length of 1,024 pixels around the image sensor 1206. Allocated areas each having a width of 512 pixels and a length of 512 pixels in the readout area are allocated to the respective A/D converters 1252, 1253, 1256, and 1257 for the A/D conversion. These A/D converters skip the readout of the signals from 384 lines, which are unnecessary pixel columns outside the irradiation area. The A/D converters 1251, 1254, 1255, and 1258 at both ends are not used in the 6-inch mode.

An image pickup control unit 1208 stops the supply of power to the A/D converters 1251, 1254, 1255, and 1258, and the rectangular semiconductor substrates, the analog multiplexers, and the amplifiers connected to the A/D converters 1251, 1254, 1255, and 1258. FIG. 13B illustrates the driving method in this case, and the signals SEL1 for the analog multiplexers 1231, 1234, 1235, and 1238 that are not used have high impedance. Similarly, the vertical start signal VST, the vertical clock CLKV, the horizontal start signal HST, the horizontal clock CLKH, and the A/D conversion clock CLKAD connected to the elements to which the supply of power is stopped each have the low level or high impedance, although not shown in FIG. 13B. The image pickup control unit 1208 combines the pieces of data from the A/D converter 1252, 1253, 1256, and 1257 to generate data on the top line and the bottom line in the image sensor 1206. The signals are read out only from the four rectangular semiconductor substrates to simplify the control. In another example, as illustrated in FIG. 13C, the readout of the signals from an upper-side portion and a lower-side portion outside the irradiation field may not be skipped.

As in the first embodiment, the conversion clock frequency in the A/D converters is 20 MHz and the flyback time at which the line is switched in the A/D conversion is one microsecond. The input switch time of the analog multiplexers is one microsecond and the time required for reset driving of the photoelectric conversion on the rectangular semiconductor substrates is one millisecond. The time to skip the readout of the signals on one line is one microsecond, which is equal to the flyback time of the line. The time required for the A/D conversion of the area having a width of 512 pixels and a length of 512 pixels corresponding to the four rectangular semiconductor substrates in the 6-inch mode under the above conditions is 17.1 milliseconds, which includes the time to skip the readout of the signals outside the irradiation area. Since the readout rate in this area is about 58.6 times per second, the readout frame rate in the irradiation area in the 6-inch mode is about 58.6 frames per second.

As described above in the first embodiment, the maximum transfer capability of an image transfer interface 1209 in the 6-inch mode is about 95 frames per second and the readout rate is about 58.6 frames per second. The maximum frame rate of the radiation imaging system in the 6-inch mode is about 58.6 frames per second because it is determined by the readout rate from the irradiation area 1205. The maximum frame rate in the 11-inch mode is 31 frames per second, as in the first embodiment. Accordingly, the throughput is further improved in the first embodiment with the readout range being limited.

Aspects of the present invention can also be realized by a computer of a system or apparatus (or devices such as a CPU or MPU) that reads out and executes a program recorded on a memory device to perform the functions of the above-described embodiments, and by a method, the steps of which are performed by a computer of a system or apparatus by, for example, reading out and executing a program recorded on a memory device to perform the functions of the above-described embodiments. For this purpose, the program is provided to the computer for example via a network or from a recording medium of various types serving as the memory device (e.g., computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-243800 filed Oct. 29, 2010, which is hereby incorporated by reference herein in its entirety.

What is claimed is:

1. An image pickup apparatus comprising:
an image sensor including a plurality of pixels that form an image pickup area;
a plurality of analog-to-digital converters configured to share a plurality of analog signals read out from the plurality of pixels to perform analog-to-digital conversion to the analog signals allocated thereto; and
a control unit configured to read out the analog signals from pixels within a partial area of the image pickup area for the analog-to-digital conversion,
wherein a number of pixels allocated to the analog-to-digital converters performing the analog-to-digital conversion to areas near a center position of the partial area is smaller than a number of pixels allocated to the analog-to-digital converters performing the analog-to-digital conversion to areas far from the center position of the partial area.

2. The image pickup apparatus according to claim 1,
wherein the control unit selectively performs first control in which the analog signals are read out from the pixels arranged in a first area in the image pickup area and second control in which the analog signals are read out from the pixels arranged in the partial area smaller than the first area.

3. The image pickup apparatus according to claim 1,
wherein the center position of the partial area substantially coincides with a center position of the image pickup area.

4. The image pickup apparatus according to claim 1,
wherein the center position of the partial area is based on a focus position of an anti-scatter grid used with the image pickup apparatus.

5. The image pickup apparatus according to claim 1, further comprising:
a setting unit configured to set a readout range in which the analog signals are read out from the pixels in the image pickup area.

6. The image pickup apparatus according to claim 1, further comprising:
a generating unit configured to generate an image based on a digital signal resulting from the analog-to-digital conversion.

7. The image pickup apparatus according to claim 1, further comprising:
a transfer unit configured to transfer an image based on a digital signal resulting from the analog-to-digital conversion.

8. The image pickup apparatus according to claim 7,
wherein the control unit skips the readout of the signals from the pixels outside the partial area, and
wherein the transfer unit cuts out an image area based on the digital signals acquired from columns outside the partial area and transfers the image resulting from the cutout.

9. The image pickup apparatus according to claim 1,
wherein the plurality of pixels are aligned in a matrix pattern of rows and columns,
wherein the image sensor further includes a plurality of row selection lines through which signals used to select the pixels on each row are transmitted and a plurality of column signal lines through which the analog signals are read out from the pixels on a selected row, and
wherein the plurality of analog-to-digital converters are connected to at least one column signal line to be connected to the pixels.

10. The image pickup apparatus according to claim 1,
wherein the image sensor further includes bases tiled thereon, the plurality of pixels being aligned on each base in a matrix pattern, and
wherein the plurality of analog-to-digital converters are connected to different bases to be connected to the pixels.

11. The image pickup apparatus according to claim 1,
wherein the plurality of analog-to-digital converters perform the analog-to-digital conversion to the plurality of analog signals read out from the plurality of pixels in units of allocated areas allocated to the plurality of analog-to-digital converters in the image pickup area in which the pixels are arranged, and the allocated areas near a certain position in the image pickup area are smaller than the allocated areas far from the certain position.

12. An image pickup apparatus comprising:
an image sensor including a plurality of pixels aligned in a matrix pattern, analog signals corresponding to an amount of detected light being read out from the pixels;
a plurality of row selection lines through which signals used to select the plurality of pixels on each row are transmitted;
a plurality of column signal lines through which the analog signals are read out from the pixels on the selected row;
a plurality of analog-to-digital converters configured to be connected to the column signal lines to perform analog-to-digital conversion to the readout analog signals; and
a control unit configured to read out the analog signals from the pixels in a central portion of the image sensor,
wherein the number of pixels connected to the analog-to-digital converters processing the signals from the pixels near a center of the image sensor is smaller than that connected to the analog-to-digital converters processing the signals from the pixels far from the center of the image sensor.

13. A radiation imaging apparatus comprising:
the image pickup apparatus according to claim 1;
an instructing unit configured to instruct execution of the control by the control unit; and
a display control unit configured to perform control so as to display image data generated in the control in response to the instruction.

14. A radiation imaging system comprising:
the image pickup apparatus according to claim 1;
a radiation source configured to irradiate the image sensor with radiation;
a changing unit configured to set an irradiation range of the radiation from the radiation source;
a generating unit configured to generate an image based on a digital signal resulting from the analog-to-digital conversion; and
a display unit configured to display the generated image.
